(19) United States
(12) Patent Application Publication
(10) Pub. No.: US 2017/0323822 A1
(43) Pub. Date: Nov. 9, 2017

(54) SYSTEMS, APPARATUS, AND METHODS FOR AN IMPROVED SUBSTRATE HANDLING ASSEMBLY

(71) Applicant: Applied Materials, Inc., Santa Clara, CA (US)

(72) Inventor: Edwin Velazquez, Union City, CA (US)

(21) Appl. No.: 15/588,592

(22) Filed: May 5, 2017

Related U.S. Application Data
(60) Provisional application No. 62/332,767, filed on May 6, 2016.

(51) Int. Cl. H01L 21/687; H01L 21/67

(52) U.S. Cl. CPC H01L 21/68707; H01L 21/67023; H01L 21/67155

(57) ABSTRACT

Embodiments of the present invention provide systems, apparatus, and methods for an improved substrate handling assembly. Embodiments include a pair of actuated arms; a pair of substrate capture tips, each capture tip formed in a different distal end of each actuated arm; an actuator coupled to a proximate end of the actuated arms and operative to actuate the actuated arms; and a hard stop positioned to prevent the actuator from closing the actuated arms more than a predefined amount so that in a closed position, the actuated arms do not contact a substrate positioned to be picked up by the substrate handing assembly. Numerous additional aspects are disclosed.

### RELATED APPLICATION

The present application claims priority from U.S. Provisional Patent Application No. 62/332,767, filed May 6, 2016, entitled “SYSTEMS, APPARATUS, AND METHODS FOR AN IMPROVED SUBSTRATE HANDLING ASSEMBLY,” (Attorney Docket No. 23938/USA/L) which is hereby incorporated herein by reference in its entirety for all purposes.

### FIELD

The present invention relates to substrate processing, and more specifically to systems, apparatus, and methods for an improved substrate handling assembly.

### BACKGROUND

The processing of substrates (e.g., semiconductor wafers) has become of great economic significance due to the large volume of integrated circuits, data disks, and similar articles being produced. The size of features used in integrated circuits have decreased significantly, thus providing greater integration and greater capacity. This has been possible due to improved lithography and other techniques and improved processing.

To some extent, the reduction in feature size has been limited by contamination. This is true because various contaminating particles, crystals, metals and organics lead to defects in the resulting products. The limitations on feature size caused by contaminants have prevented full utilization of the resolution capability of known manufacturing techniques. Thus there remains an acute need for improved methods and systems for processing substrates and similar articles requiring very low levels of contamination during processing. In addition, substrates can be extremely fragile and prone to damage. Thus, there is a need for a robot that can handle substrates without damaging the substrates and without generating contaminants.

### SUMMARY

In some embodiments, the present invention provides an apparatus for an improved substrate handling assembly. The improved substrate handling assembly includes a pair of actuated arms; a pair of substrate capture tips, each capture tip formed in a different distal end of each actuated arm; an actuator coupled to a proximate end of the actuated arms and operative to actuate the actuated arms; and a hard stop positioned to prevent the actuator from closing the actuated arms more than a predefined amount so that in a closed position, the actuated arms do not contact a substrate positioned to be picked up by the substrate handing assembly.

In some embodiments, the present invention provides an improved method of handling a substrate. The improved method of handling a substrate includes positioning a pair of substrate capture tips of a substrate handling assembly below a center of a vertically positioned substrate; moving the capture tips toward each other so that a distance between the capture tips is less than a diameter of the substrate; and raising the capture tips to engage an edge of the substrate and to secure the substrate in a substrate pocket formed by the capture tips.

In some embodiments, the present invention provides a running beam robot with an improved substrate handling assembly. The running beam robot includes a gantry spanning above a plurality of processing stations; a substrate handling assembly suspended from the gantry and adapted to be moved along the gantry to each of the processing stations; an elevator adapted to raise and lower the substrate handling assembly; and a controller operative to control operation and positioning of the substrate handling assembly. The substrate handling assembly includes a pair of actuated arms; a pair of substrate capture tips, each capture tip formed in a different distal end of each actuated arm; an actuator coupled to a proximate end of the actuated arms and operative to actuate the actuated arms; and a hard stop positioned to prevent the actuator from closing the actuated arms more than a predefined amount so that in a closed position, the actuated arms do not contact a substrate positioned to be picked up by the substrate handing assembly.

Other features, aspects, and advantages of the present invention will become more fully apparent from the following detailed description, the appended claims, and the accompanying drawings by illustrating a number of example embodiments and implementations. Embodiments of the present invention may also be capable of other and different applications, and its several details may be modified in various respects, all without departing from the spirit and scope of the present invention. Accordingly, the drawings and descriptions are to be regarded as illustrative in nature, and not as restrictive. The drawings are not necessarily drawn to scale.

### BRIEF DESCRIPTION OF THE DRAWINGS

FIG. 1 is a schematic diagram depicting a first example embodiment of an improved substrate handling assembly in a first position according to embodiments of the present invention.

FIG. 2 is a schematic diagram depicting a first example embodiment of an improved substrate handling assembly in a second position according to embodiments of the present invention.

FIG. 3 is a schematic diagram depicting a first example embodiment of an improved substrate handling assembly in a third position according to embodiments of the present invention.

FIGS. 4A and 4B are schematic diagram depicting a front view and a cross-sectional side view respectively of an example embodiment of an improved substrate handling assembly system according to embodiments of the present invention.

FIG. 5 is a schematic diagram depicting a magnified cross-sectional side view of a portion of the example embodiment of FIGS. 4A and 4B.

FIGS. 6A, 6B and 6C are schematic diagrams depicting magnified isometric, front, and side views respectively of an example embodiment of capture tips of the example embodiment of FIGS. 4A and 4B.

FIG. 7 is a flowchart depicting an example method of handling a substrate according to embodiments of the present invention.

FIG. 8 is a schematic diagram depicting a perspective view of an example of a robot including improved substrate handling assemblies according to embodiments of the present invention.

### DESCRIPTION

Embodiments of the present invention provide systems, apparatus, and methods for an improved substrate handling assembly. In particular, embodiments of the present invention provide a solution to issues with existing substrate handling assemblies. For example, to avoid damaging the substrates, existing substrate handling assemblies have marginal gripping force. This causes handling issues such as dropped substrates or substrates being left behind in a current location holder. Also, existing substrate handling assemblies that are clamping or gripping designs, impact the substrate when closing. This can produce unwanted stress on the substrate. In addition, the existing designs typically use sleeve bushings and a thrust washer which create a high friction design. These design elements contribute to potentially contaminating particulate generation and to the low gripping force.

Existing substrate handling assemblies that use a pivot design are typically configured so that the gripping arms, sleeve bushings, and thrust washer are stacked and compressed by a cap and o-ring. Due to the typical tolerance range of these types of assemblies, the amount of compression can vary greatly from assembly to assembly. In addition, the tolerance range allows assemblies to have no compression or open gapping. This results in gripper arms that are allowed to float laterally along the pivot shaft which introduces positioning errors when attempting to pick up and drop off substrates.

Embodiments of the substrate handling assembly of the present invention eliminates these issues. The friction, particulate generation, and tolerance stacking are eliminated via the use of a sealed roller bearing design that allows the assembly to have near friction free movement with minimum particulate generation that is contained in the sealed bearings. Embodiments of the substrate handling assembly of the present invention are preloaded to eliminate any stacking issues. Embodiments of the substrate handling assembly of the present invention also uses a more powerful actuator (e.g., a larger cylinder) than used previously that allows a substantial increase of the gripping force over existing assemblies.

Embodiments of the substrate handling assembly of the present invention also include a substrate pocket that allows the substrate to be picked up without having to apply pressure to the substrate as the arms close around the substrate. This eliminates stress and possible damage to the substrate. The substrate pocket is formed within capture tips that include contours for holding the substrate.

Embodiments of the present invention provide a substrate handling assembly that has open/close actuating arms, but operates as a pocket holder to pick up and place the substrate. The design allows the assembly to position directly above the substrate with the actuating arms in the open position. This allows the actuating arms to lower over the substrate and position the arms so that the capture tips of the arms are below the substrate center. The actuating arms are actuated to the close position, limited by a hard stop, and still not contacting the substrate. Then, as the assembly is moved upward, the substrate is securely captured in the pocket features in the capture tips and then lifted out of the current location. The substrate only experiences the force due to gravity and is not compressed or otherwise stressed by the substrate handling assembly.

To place the substrate, the assembly lowers until the substrate is placed in the destination holder. The assembly then continues to lower until the capture tips at the end of the actuating arms are no longer in contact with the substrate. The arms are then actuated to the open position. The assembly is then clear of the substrate and able to be lifted out of the destination without further contacting the substrate.

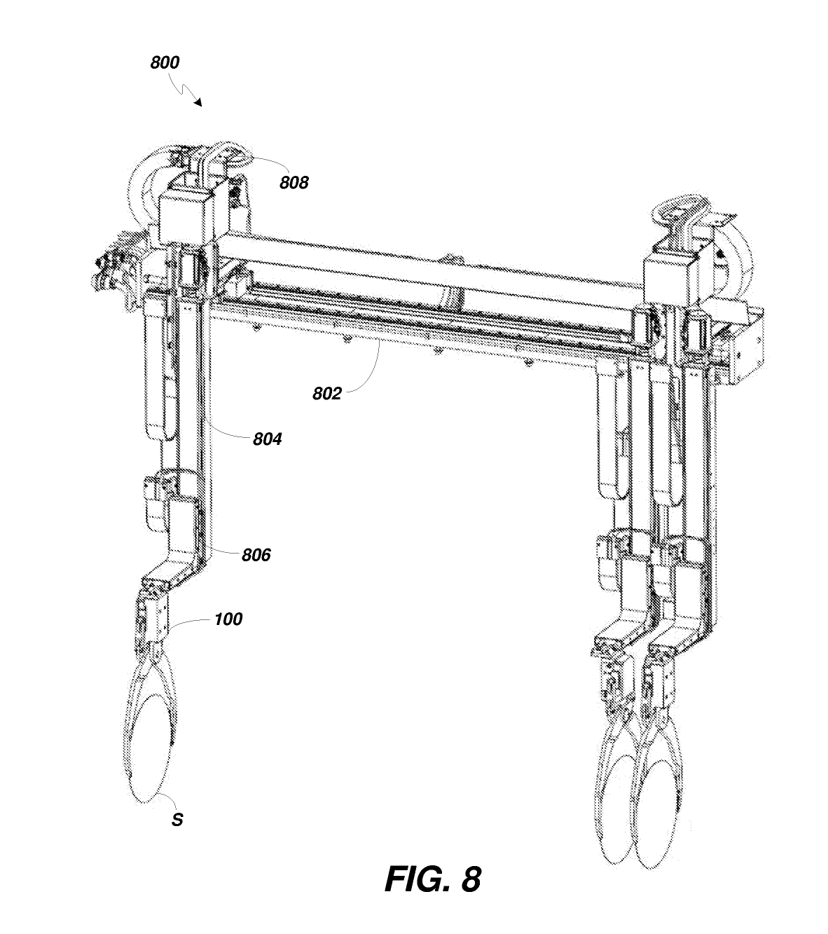

The substrate handling assembly of embodiments of the present invention is suitable for use with a robot 800 (e.g., a running beam robot) such as that pictured in FIG. 8. Such a robot 800 can include a gantry 802 spanning above a plurality of processing stations (not shown). The processing stations can include submersion tanks and rinsing stations that apply various process chemicals to the substrates S. The gantry 802 facilitates moving substrates S between the stations. One or more (three are pictured) substrate handling assemblies 100 are suspended from the gantry 802 via a linkage 804 and are adapted to be moved along the gantry 802 to each of the processing stations. An elevator 806, adapted to raise and lower the substrate handling assembly 100, is provided on the linkage 804 between the gantry 802 and the substrate handling assembly 100. The system also includes a controller 808 operative to control operation and positioning of the substrate handling assembly 100.

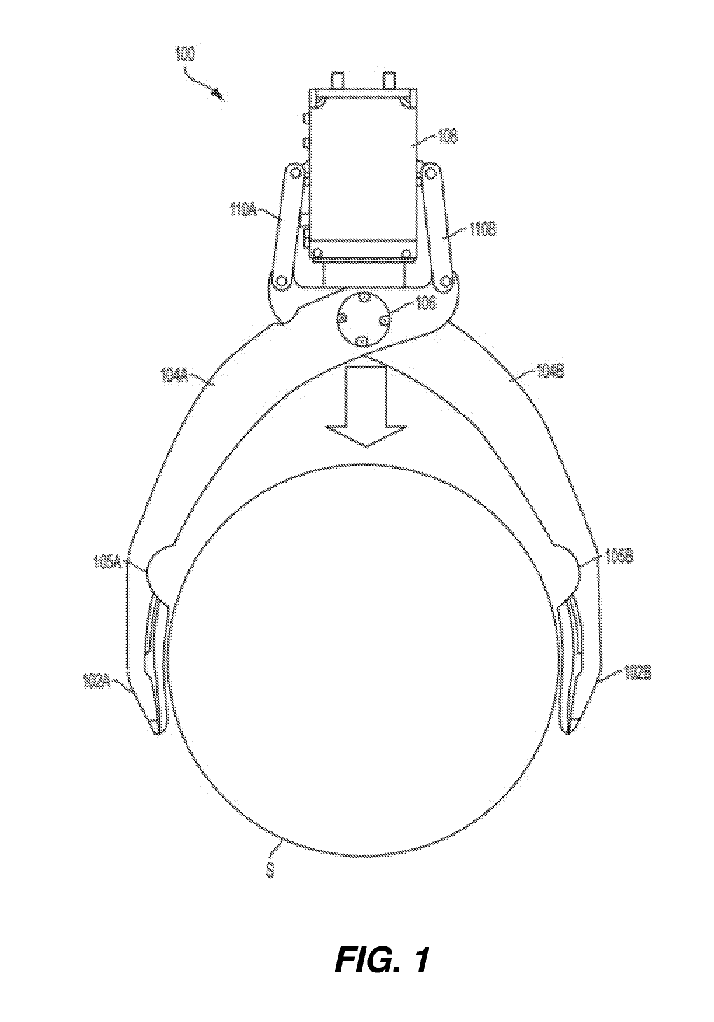

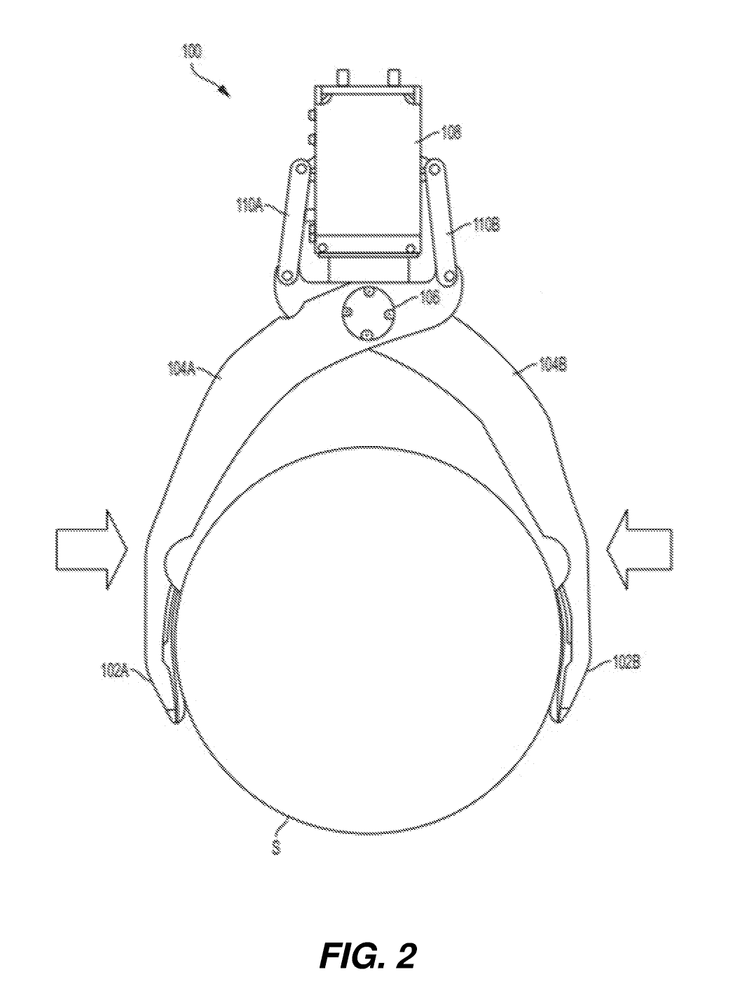

Turning now to FIGS. 1 through 3, an example sequence for lifting a substrate S (e.g., a round 300 mm silicon wafer) using a substrate handling assembly 100 of embodiments of the present invention is illustrated. The substrate handling assembly 100 includes a pair of substrate capture tips 102A, 102B formed at the distal ends of actuated arms 104A, 104B. In some embodiments, the actuated arms 104A, 104B include curved members dimensioned to surround the substrate S as shown in FIG. 1. The actuated arms 104A, 104B can include calibration cutouts 105A, 105B that provide visual access for an operator to allow the substrate handling assembly 100 to be aligned with a substrate S during initial system set up. In some embodiments, the actuated arms 104A, 104B are configured to be moved together and apart by rotating about a pivot assembly 106 driven by an actuator 108 coupled to the actuated arms 104A, 104B via linkages 110A, 110B. For example, as illustrated in FIGS. 1 and 2, the actuated arms 104A, 104B are operative to move between an open position as shown in FIG. 1 and a closed position as shown in FIG. 2. In the illustrated embodiment, the substrate handling assembly 100 operates using a scissor action in that the actuated arms 104A, 104B pivot relative to each other. In alternative embodiments, the arms can be adapted to move in a linear motion to close around the substrate without using a pivot.

As indicated by the downwardly pointing arrow shown in FIG. 1, when the substrate handling assembly 100 is in the open position, the capture tips 102A, 102B do not contact the substrate S and can be moved vertically down into (and up out of) position without colliding with the substrate S. When opening the substrate handling assembly 100, the actuator 108 moves the actuated arms 104A, 104B to stop at a predefined distance apart. In some embodiments, an adjustable hard stop can be used to precisely limit the actuator 108 and control the range of opening motion of the actuated arms 104A, 104B. In some embodiments, the substrate capture tips 102A, 102B are separated in the open position so that they are a distance apart that is greater than the maximum width (e.g., the diameter) of the substrate S. For example, for a circular 300 mm substrate, the capture tips 102A, 102B can be separated so that they are approximately 305 mm to approximately 330 mm apart in the open position. In another example, for a circular 400 mm substrate, the capture tips 102A, 102B can be separated so that they are approximately 405 mm to approximately 430 mm apart in the open position. In other embodiments, other predefined distances can be used for the open position.

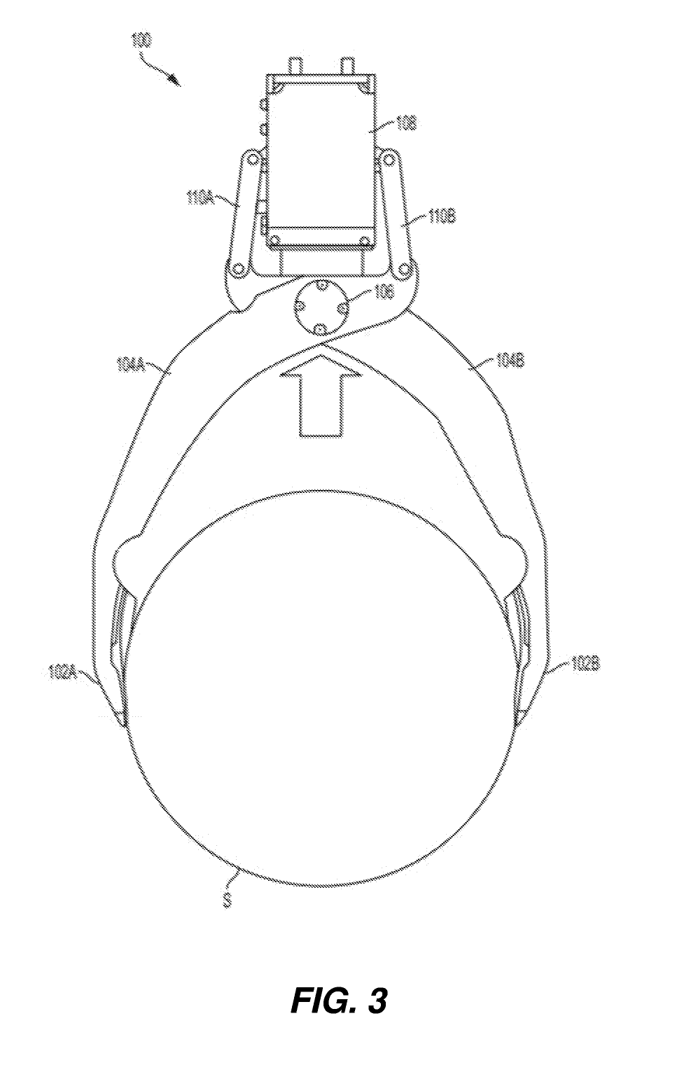

As indicated by the two inward pointing arrows shown in FIG. 2, when the substrate handling assembly 100 is moved to the closed position, the capture tips 102A, 102B still do not contact the substrate S (until the substrate handling assembly 100 is raised up vertically as shown in FIG. 3). The actuator 108 brings the actuated arms 104A, 104B to stop at a predefined distance apart without contacting the substrate S. In some embodiments, an adjustable hard stop can be used to precisely limit the actuator 108 and control the range of closing motion of the actuated arms 104A, 104B. In some embodiments, the substrate capture tips 102A, 102B are brought together in the closed position so that they are a distance apart that is less than the maximum width (e.g., the diameter) of the substrate S. For example, for a circular 300 mm substrate, the capture tips 102A, 102B can be brought together so that they are approximately 270 mm to approximately 295 mm apart in the closed position. In another example, for a circular 400 mm substrate, the capture tips 102A, 102B can be brought together so that they are approximately 370 mm to approximately 395 mm apart in the closed position. In other embodiments, other predefined distances can be used for the closed position. Note that in some embodiments as shown in FIG. 2, the actuated arms 104A, 104B can include lead-in features that provide a kinematic surface to guide a slightly out of position substrate S to align with the substrate handling assembly 100 as the actuated arms 104A, 104B close toward the substrate S. Thus, the portions of the actuated arms 104A, 104B that is obscured by the substrate S in FIG. 1 are the lead-in features and do not necessarily contact the substrate S if it is in proper position.

As shown in FIG. 3, with the substrate handling assembly 100 in the closed position and the capture tips 102A, 102B disposed below the center of the substrate S, the substrate handling assembly 100 is moved vertically upwards. This upward motion in the closed position causes the capture tips 102A, 102B to engage the edge of the substrate S and securely capture the substrate S in a substrate pocket formed by the capture tips 102A, 102B.

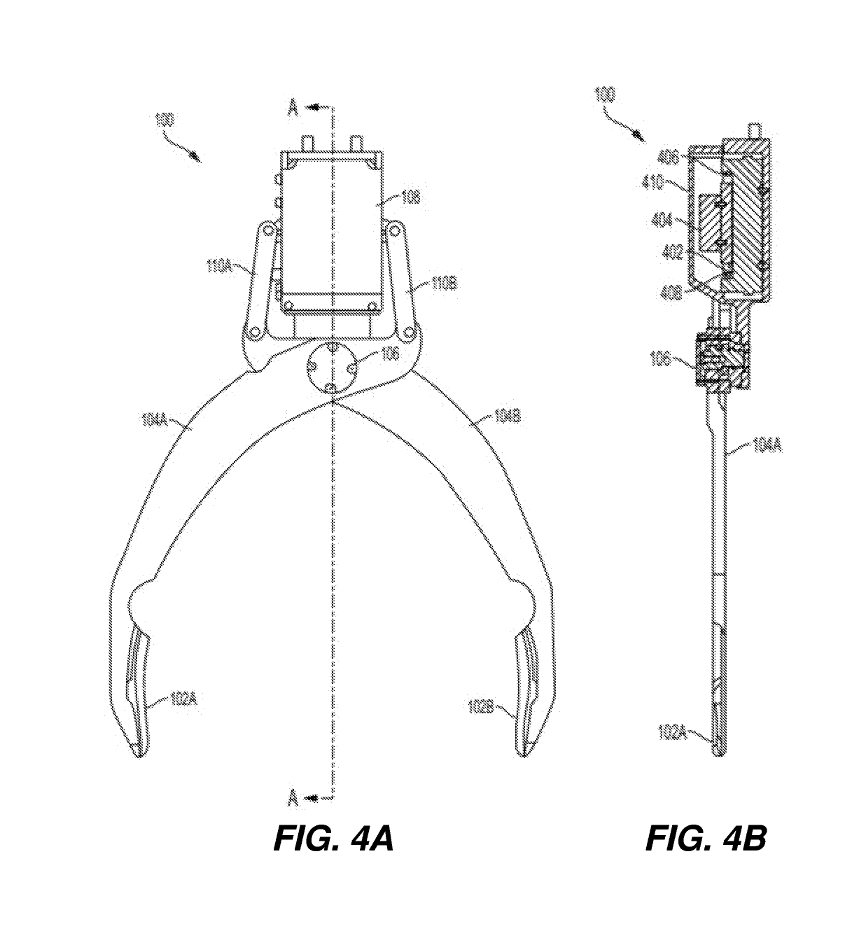

Turning now to FIGS. 4A & 4B, details of the actuator 108 are illustrated. FIG. 4A depicts a front view of the substrate handling assembly 100 and FIG. 4B depicts a side cross-sectional view taken along line AA in FIG. 4A. As shown, the example embodiment of an actuator 108 can include a pneumatic or hydraulic cylinder 402 that is operative to move a slide block 404 up to an adjustable upper hard stop 406 and downward to an adjustable lower hard stop 408. Other types of actuators (e.g., electrical) can be used. The slide block 404 is pivotally coupled to the linkages 110A and 110B which are pivotally coupled to the actuated arms 104A, 104B. In some embodiments, the adjustable upper hard stop 406 and the adjustable lower hard stop 408 are embodied as bolts (e.g., hex head bolts) that can be turned to adjust their vertical position. The actuator 108 also includes a cover 410 that contains any particles generated by the actuator 108.

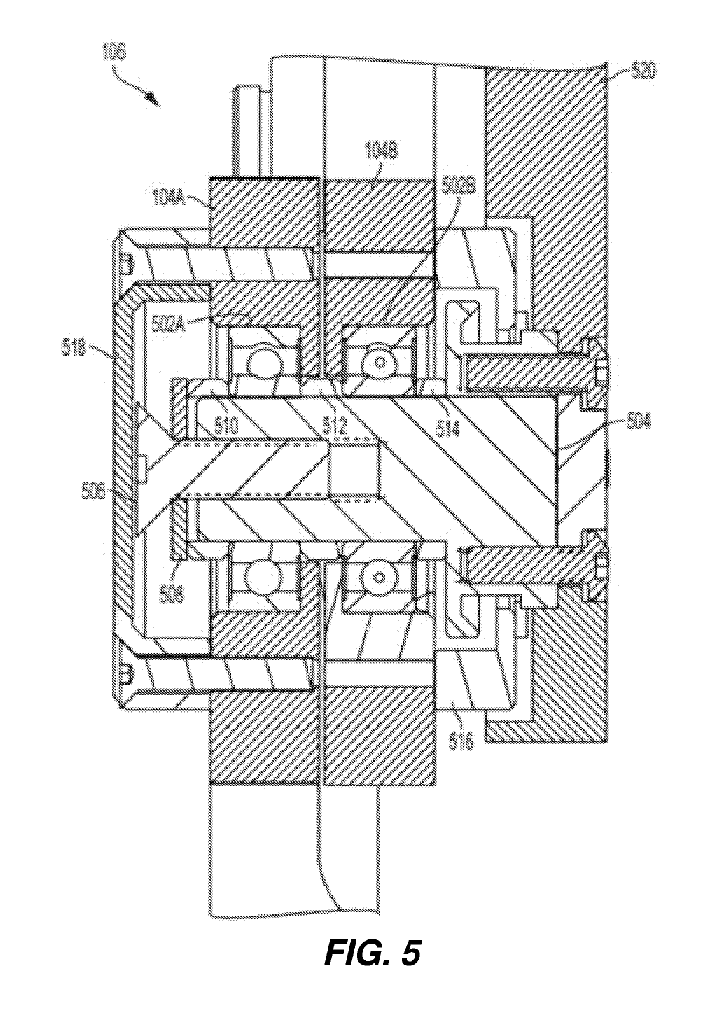

FIG. 5 is a magnified cross-sectional view of the pivot assembly 106 taken along line AA in FIG. 4A. As shown, the pivot assembly 106 can include a pair of sealed roller bearings 502A, 502B disposed around a pivot shaft 504 and held in place with a pre-load screw 506 and pre-load washer 508. The roller bearings 502A, 502B are coupled to the actuated arms 104A, 104B and held at optimal fixed spacing using bearing spacers 510, 512, 514. Thus, unlike prior art designs that allow the gripper arms to float along a pivot shaft, embodiments of the present invention provide a much more precise (e.g., tighter tolerance) pivot assembly 106 that does not have variable rotational friction based on the tightness of the fastener holding the assembly together or gaps and float. The pivot assembly 106 also includes sealing caps 516, 518 and is protected by a housing 520, both to further contain any generated particles and to prevent exposure to processing fluids.

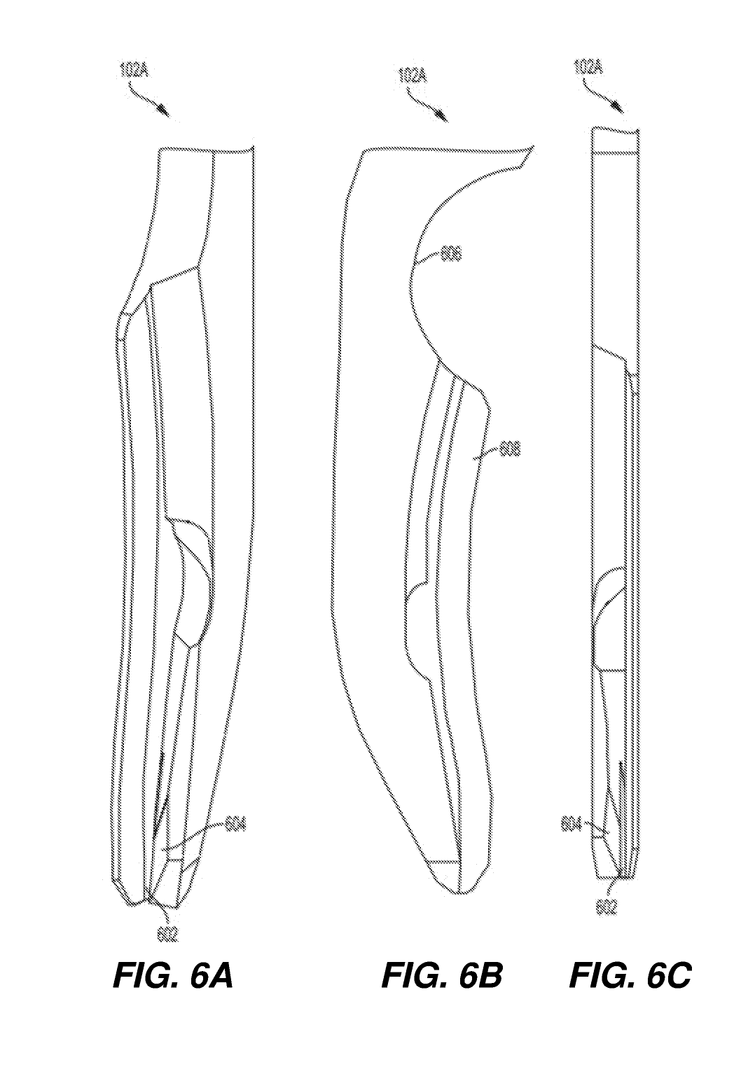

FIGS. 6A, 6B and 6C are a magnified isometric, front and side views respectively of a capture tip 102A. Note that capture tip 102B is a mirror image of capture tip 102A. The capture tip 102A includes groove 602 that is adapted to receive and contact the edge of a substrate S. Upon lifting the substrate handling assembly, the substrate S is guided into the groove 602 by kinematic surface 604. Together, the groove 602 on each of the capture tips 102A, 102B forms a substrate pocket adapted to support and securely hold a substrate S when the capture tips 102A, 102B are positioned at the pre-defined distance apart (e.g., the closed position illustrated in FIGS. 2 and 3). In some embodiments, the capture tips 102A, 102B each include a lead-in feature 606 (e.g., a kinematic surface) that allows the substrate handling assembly 100 to guide a misaligned substrate into position upon moving the substrate handling assembly 100 to the closed position. In some embodiments, the capture tip 102A can include a cutout 608 to further improve clearance during operation and also to provide milling tool access during manufacturing of the groove 602. In some embodiments, the capture tips 102A, 102B and the actuated arms 104A, 104B can be made from any suitable form of plastic (e.g., PEEK, Polypro, PET, etc.) or type of metal (e.g., stainless steel, aluminum, etc.). Other materials can alternatively be used. In alternative embodiments, a different material can be used for the capture tips than for the remainder of the arms.

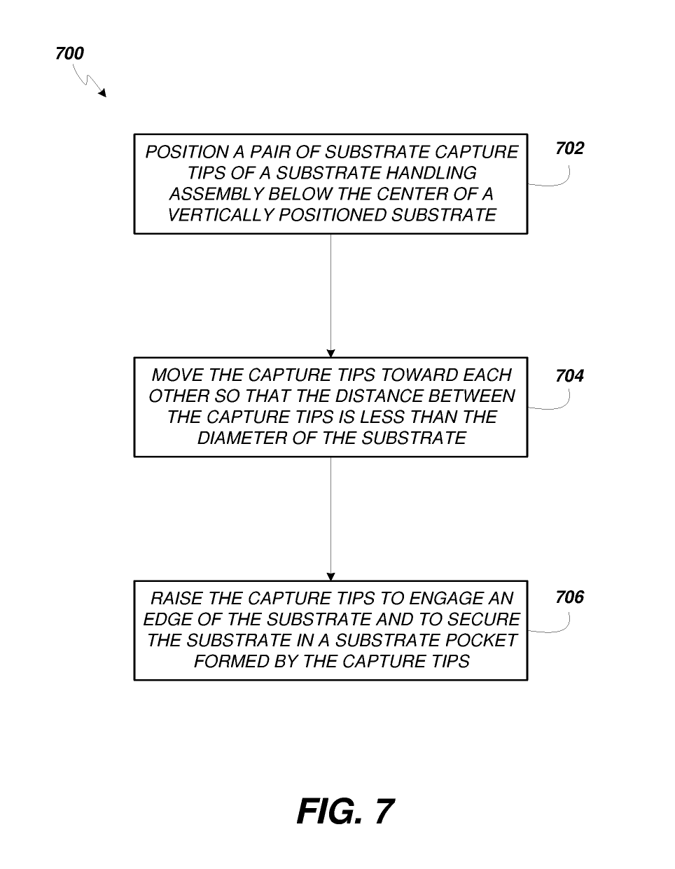

Turning now to FIG. 7, a flowchart depicting an example method of handling a substrate is provided. The method includes positioning a pair of substrate capture tips of a substrate handling assembly below the center of a vertically positioned substrate (702). This involves aligning the assembly above the substrate in, for example, a processing tank and submerging the actuated arms in the open position to surround the substrate as in FIG. 1. Next, the capture tips are moved toward each other so that the distance between the capture tips is less than a diameter of the substrate (704). The actuated arms are moved to a closed position as in FIG. 2. Finally, the capture tips are raised to engage the edge of the substrate and to secure the substrate in the substrate pocket formed by the capture tips (706). The substrate handling assembly is lifted so that the substrate pocket captures the substrate as shown in FIG. 3.

Numerous embodiments are described in this disclosure, and are presented for illustrative purposes only. The described embodiments are not, and are not intended to be, limiting in any sense. The presently disclosed inventions are widely applicable to numerous embodiments, as is readily apparent from the disclosure. One of ordinary skill in the art will recognize that the disclosed inventions may be practiced with various modifications and alterations, such as structural, logical, software, and electrical modifications. Although particular features of the disclosed inventions may be described with reference to one or more particular embodiments and/or drawings, it should be understood that such features are not limited to usage in the one or more particular embodiments or drawings with reference to which they are described, unless expressly specified otherwise.

The present disclosure is neither a literal description of all embodiments nor a listing of features of the invention that must be present in all embodiments.

The Title (set forth at the beginning of the first page of this disclosure) is not to be taken as limiting in any way as the scope of the disclosed inventions.

The present disclosure provides, to one of ordinary skill in the art, an enabling description of several embodiments and/or inventions. Some of these embodiments and/or inventions may not be claimed in the present application, but may nevertheless be claimed in one or more continuing applications that claim the benefit of priority of the present application. Applicants intend to file additional applications to pursue patents for subject matter that has been disclosed and enabled but not claimed in the present application.

The foregoing description discloses only example embodiments of the invention. Modifications of the above-disclosed apparatus, systems and methods which fall within the scope of the invention will be readily apparent to those of ordinary skill in the art.

Accordingly, while the present invention has been disclosed in connection with example embodiments thereof, it should be understood that other embodiments may fall within the spirit and scope of the invention, as defined by the following claims.

The invention claimed is:

1. A substrate handling assembly comprising:
a pair of actuated arms;
a pair of substrate capture tips, each capture tip formed in a different distal end of each actuated arm;
an actuator coupled to a proximate end of the actuated arms and operative to actuate the actuated arms; and
a hard stop positioned to prevent the actuator from closing the actuated arms more than a predefined amount so that in a closed position, the actuated arms do not contact a substrate positioned to be picked up by the substrate handing assembly.

2. The substrate handling assembly of claim 1 further comprising a pivot assembly including a pair of roller bearings, each roller bearing being coupled to a different actuated arm at a pivot location.

3. The substrate handling assembly of claim 1 wherein the pair of actuated arms are arranged in a scissors configuration.

4. The substrate handling assembly of claim 1 wherein the capture tips include a contoured substrate pocket configured to capture a substrate when lifted vertically from below a center of a substrate that is in a vertical orientation.

5. The substrate handling assembly of claim 4 wherein the contoured substrate pocket includes kinematic lead-in surfaces adapted to guide a substrate edge into a groove of the substrate pocket as the capture tips are lifted vertically from below the center of the substrate.

6. The substrate handling assembly of claim 1 wherein the actuator includes at least one of a pneumatic cylinder and a hydraulic cylinder.

7. The substrate handling assembly of claim 1 wherein the actuated arms are adapted to be submersed into a fluid to pick up and place a substrate.

8. A running beam robot comprising:
a gantry spanning above a plurality of processing stations;
a substrate handling assembly suspended from the gantry and adapted to be moved along the gantry to each of the processing stations;
an elevator adapted to raise and lower the substrate handling assembly; and
a controller operative to control operation and positioning of the substrate handling assembly, wherein the substrate handling assembly includes:
a pair of actuated arms;
a pair of substrate capture tips, each capture tip formed in a different distal end of each actuated arm;
an actuator coupled to a proximate end of the actuated arms and operative to actuate the actuated arms; and
a hard stop positioned to prevent the actuator from closing the actuated arms more than a predefined amount so that in a closed position, the actuated arms do not contact a substrate positioned to be picked up by the substrate handing assembly.

9. The running beam robot of claim 8 wherein the substrate handling assembly further includes a pivot assembly including a pair of roller bearings, each roller bearing being coupled to a different actuated arm at a pivot location.

10. The running beam robot of claim 8 wherein the pair of actuated arms are arranged in a scissors configuration.

11. The running beam robot of claim 8 wherein the capture tips include a contoured substrate pocket configured to capture a substrate when lifted vertically from below a center of a substrate that is in a vertical orientation.

12. The running beam robot of claim 11 wherein the contoured substrate pocket includes kinematic lead-in surfaces adapted to guide a substrate edge into a groove of the substrate pocket as the capture tips are lifted vertically from below the center of the substrate.

13. The running beam robot of claim 8 wherein the actuator includes at least one of a pneumatic cylinder and a hydraulic cylinder.

14. The running beam robot of claim 8 wherein the actuated arms are adapted to be submersed into a fluid to pick up and place a substrate.

15. A method of handling a substrate, the method comprising:
positioning a pair of substrate capture tips of a substrate handling assembly below a center of a vertically positioned substrate;
moving the capture tips toward each other so that a distance between the capture tips is less than a diameter of the substrate; and
raising the capture tips to engage an edge of the substrate and to secure the substrate in a substrate pocket formed by the capture tips.

16. The method of claim 15 further comprising providing the substrate handling assembly including:
a pair of actuated arms;
the pair of substrate capture tips, each capture tip formed in a different distal end of each actuated arm;
an actuator coupled to a proximate end of the actuated arms and operative to actuate the actuated arms; and
a hard stop positioned to prevent the actuator from closing the actuated arms more than a predefined amount so that in a closed position, the actuated arms do not contact the substrate positioned to be picked up by the substrate handing assembly.

17. The method of claim 16 wherein positioning the pair of substrate capture tips of the substrate handling assembly below the center of the vertically positioned substrate includes lowering the actuated arms of the substrate handling assembly in an open position into a fluid tank so that the actuated arms are disposed surrounding the substrate.

18. The method of claim 17 wherein moving the capture tips toward each other includes operating the actuator to move the actuated arms to a closed position.

19. The method of claim 18 wherein the capture tips and actuated arms are moved to the closed position without contacting the substrate.

20. The method of claim 19 wherein raising the capture tips to engage the edge of the substrate includes lifting the substrate handling assembly out of the fluid tank.
